(19) United States
(12) Patent Application Publication
(10) Pub. No.: US 2014/0174353 A1
(43) Pub. Date: Jun. 26, 2014

(54) HIGH-TEMPERATURE GRADE STEEL FOR FLUIDIZED BED REACTOR EQUIPMENT

(71) Applicant: REC Silicon Inc, Moses Lake, WA (US)

(72) Inventors: Michael V. Spangler, Soap Lake, WA (US); Matthew J. Miller, Moses Lake, WA (US)

(73) Assignee: REC Silicon Inc, Moses Lake, WA (US)

(21) Appl. No.: 14/109,762

(22) Filed: Dec. 17, 2013

Related U.S. Application Data
(60) Provisional application No. 61/745,377, filed on Dec. 21, 2012.

(51) Int. Cl. C23C 16/442; C23C 16/44

(52) U.S. Cl. CPC C23C 16/442; C23C 16/4417
USPC 118/716

(57) ABSTRACT

Embodiments of a reaction chamber liner for use in a heated silicon deposition reactor are disclosed. The liner has an upper portion, a mid portion comprising a material other than a stainless steel alloy, and a lower portion comprising a martensitic stainless steel alloy. The liner's upper portion may have a composition substantially similar to the lower portion.

### CROSS REFERENCE TO RELATED APPLICATION

This claims the benefit of U.S. Provisional Application No. 61/745,377, filed Dec. 21, 2012, which is incorporated herein by reference in its entirety.

### FIELD

The present disclosure relates to a liner for use with a fluid bed reactor, such as a fluid bed reactor for pyrolytic decomposition of a silicon-bearing gas to produce silicon-coated particles.

### BACKGROUND

Pyrolytic decomposition of silicon-bearing gas in fluidized beds is an attractive process for producing polysilicon for the photovoltaic and semiconductor industries due to excellent mass and heat transfer, increased surface for deposition, and continuous production. Compared with a Siemens-type reactor, the fluidized bed reactor offers considerably higher production rates at a fraction of the energy consumption. The fluidized bed reactor can be continuous and highly automated to significantly decrease labor costs.

The manufacture of particulate polycrystalline silicon by a chemical vapor deposition method involving pyrolysis of a silicon-containing substance such as for example silane, disilane or halosilanes such as trichlorosilane or tetrachlorosilane in a fluidized bed reactor is well known to a person skilled in the art and exemplified by many publications including the following patents and publications: U.S. Pat. No. 8,075,692, U.S. Pat. No. 7,029,632, U.S. Pat. No. 5,810,934, U.S. Pat. No. 5,798,137, U.S. Pat. No. 5,139,762, U.S. Pat. No. 5,077,028, U.S. Pat. No. 4,883,687, U.S. Pat. No. 4,868,013, U.S. Pat. No. 4,820,587, U.S. Pat. No. 4,416,913, U.S. Pat. No. 4,314,525, U.S. Pat. No. 3,012,862, U.S. Pat. No. 3,012,861, US2010/0215562, US2010/0068116, US2010/0047136, US2010/0044342, US2009/0324479, US2008/0299291, US2009/0004090, US2008/0241046, US2008/0056979, US2008/0220166, US 2008/0159942, US2002/0102850, US2002/0086530, and US2002/0081250.

Silicon is deposited on particles in a reactor by decomposition of a silicon-bearing gas selected from the group consisting of silane (SiH₄), disilane (Si₂H₆), higher order silanes (SiₙH₂ₙ₊₂), dichlorosilane (SiH₂Cl₂), trichlorosilane (SiHCl₃), silicon tetrachloride (SiCl₄), dibromosilane (SiH₂Br₂), tribromosilane (SiHBr₃), silicon tetrabromide (SiBr₄), diiodosilane (SiH₂I₂), triiodosilane (SiHI₃), silicon tetraiodide (SiI₄), and mixtures thereof. The silicon-bearing gas may be mixed with one or more halogen-containing gases, defined as any of the group consisting of chlorine (Cl₂), hydrogen chloride (HCl), bromine (Br₂), hydrogen bromide (HBr), iodine (I₂), hydrogen iodide (HI), and mixtures thereof. The silicon-bearing gas may also be mixed with one or more other gases, including hydrogen (H₂) or one or more inert gases selected from nitrogen (N₂), helium (He), argon (Ar), and neon (Ne). In particular embodiments, the silicon-bearing gas is silane, and the silane is mixed with hydrogen. The silicon-bearing gas, along with any accompanying hydrogen, halogen-containing gases and/or inert gases, is introduced into a fluidized bed reactor and thermally decomposed within the reactor to produce silicon which deposits upon seed particles inside the reactor.

A common problem in fluidized bed reactors is contamination of the fluid bed at high operating temperatures by materials used to construct the reactor and its components. For example, nickel has been shown to diffuse into a silicon layer on a fluidized particle from the base metal in some alloys containing nickel. Ceramic liners can be used to minimize contamination. However, the ceramic liner is subjected to tremendous thermal and mechanical stresses over its length, making it highly susceptible to mechanical failure.

### SUMMARY

Embodiments of a reaction chamber liner for use in a heated silicon deposition reactor have an inner surface configured to define a portion of a reaction chamber. The liner includes an upper portion, a mid portion comprising a material other than a stainless steel alloy, and a lower portion, wherein at least a portion of the inner surface is a martensitic stainless steel alloy. The liner's upper portion may have a composition substantially similar to the lower portion.

In some embodiments, the stainless steel alloy comprises less than 20% (w/w) chromium, such as 11-18% (w/w) chromium, and less than 3% (w/w) nickel, such as less than 1% (w/w) nickel. In one embodiment, the stainless steel alloy does not include copper or selenium.

In one embodiment, the stainless steel alloy includes 11.5-13.5% (w/w) chromium and 0.7-0.8% (w/w) nickel. In another embodiment, the alloy includes 12-14% (w/w) chromium and less than 0.5% (w/w) nickel. In either of these embodiments, the alloy further may include ≦0.15% (w/w) carbon, ≦1% (w/w) silicon, ≦1% (w/w) manganese, ≦0.04% (w/w) phosphorus, and ≦0.03% (w/w) sulfur.

In another embodiment, the stainless steel alloy includes 16-18% (w/w) chromium and less than 0.5% (w/w) nickel. The alloy may further include 0.5-1.5% (w/w) carbon, ≦1% (w/w) silicon, ≦1% (w/w) manganese, ≦0.04% (w/w), phosphorus, and ≦0.03% (w/w) sulfur.

In some embodiments, the stainless steel alloy has a Rockwell hardness greater than 40 Re, such as a Rockwell hardness of 45-60 Rc.

Advantageously, the stainless steel alloy has a mean coefficient of thermal expansion less than 15×10⁻⁶ m/m·° C. over a temperature range from 0° C.-315° C. In some embodiments, the mean coefficient of thermal expansion is from 9.9×10⁻⁶ m/m·° C. to 11.5×10⁻⁶ m/m·° C. In one embodiment, the mean coefficient of thermal expansion is 10.7×10⁻⁶ m/m·° C. to 10.9×10⁻⁶ m/m·° C. In another embodiment, the mean coefficient of thermal expansion is 11.3×10⁻⁶ m/m·° C. to 11.5×10⁻⁶ m/m·° C. In yet another embodiment, the mean coefficient of thermal expansion is 10.0×10⁻⁶ m/m·° C. to 10.2×10⁻⁶ m/m·° C.

In some embodiments, the lower portion of the liner is prepared by machining a body of the stainless steel alloy and subsequently hardening and optionally tempering the stainless steel alloy by heat treatment.

In some embodiments, at least a portion of the inner surface of the liner's mid portion is a ceramic, graphite, or glass. In certain embodiments, the mid portion consists essentially of the ceramic, graphite, or glass. In one embodiment, the ceramic is silicon carbide. In another embodiment, the ceramic is silicon nitride. In one embodiment, the glass is quartz.

Embodiments of the disclosed liner are suitable for use in a heated silicon deposition reactor. The reactor may include a vessel having an outer wall, at least one heater position inwardly of the outer wall, a liner positioned inwardly of the at least one heater such that the inner surface of the liner defines a portion of a reaction chamber, at least one inlet having an opening positioned to admit a primary gas comprising a silicon-bearing gas into the reaction chamber, a plurality of fluidization inlet, wherein each fluidization inlet has an outlet opening into the reaction chamber, and at least one outlet for removing silicon-coated product particles from the vessel.

The foregoing and other objects, features, and advantages of the invention will become more apparent from the following detailed description, which proceeds with reference to the accompanying figures.

### BRIEF DESCRIPTION OF THE DRAWINGS

FIG. 1 is a schematic cross-sectional view of an exemplary fluidized bed reactor.

FIG. 2 is a schematic diagram of one embodiment of a liner for a fluidized bed reactor.

### DETAILED DESCRIPTION

Unless otherwise indicated, all numbers expressing properties such as percentages, thermal expansion coefficients and so forth, as used in the specification or claims are to be understood as being modified by the term “about.” Unless otherwise indicated, non-numerical properties such as amorphous, crystalline, homogeneous, and so forth as used in the specification or claims are to be understood as being modified by the term “substantially,” meaning to a great extent or degree. Accordingly, unless otherwise indicated, implicitly or explicitly, the numerical parameters and/or non-numerical properties set forth are approximations that may depend on the desired properties sought, limits of detection under standard test conditions/methods, limitations of the processing method, and/or the nature of the parameter or property. When directly and explicitly distinguishing embodiments from discussed prior art, the embodiment numbers are not approximates unless the word “about” is recited.

Disclosed herein are embodiments of a liner for use in a fluid bed reactor system, such as a fluid bed reactor system for the formation of polysilicon by pyrolytic decomposition of a silicon-bearing gas and deposition of silicon onto fluidized silicon particles or other seed particles (e.g., silica, graphite, or quartz particles). Preferably, a liner for a fluid bed reactor produces little or no contamination of the fluidized particles. Desirable liner materials include ceramics (e.g., silicon carbide, silicon nitride), graphite, and glasses (e.g., quartz). However, a liner in a fluid bed reactor is subjected to tremendous thermal and mechanical stresses along its length. Ceramic, graphite, and glass liners are highly susceptible to mechanical failure, such as cracking and/or fracturing, and may not remain intact during reactor operation. Embodiments of the disclosed liner reduce the mechanical and thermal stresses while also minimizing product contamination.

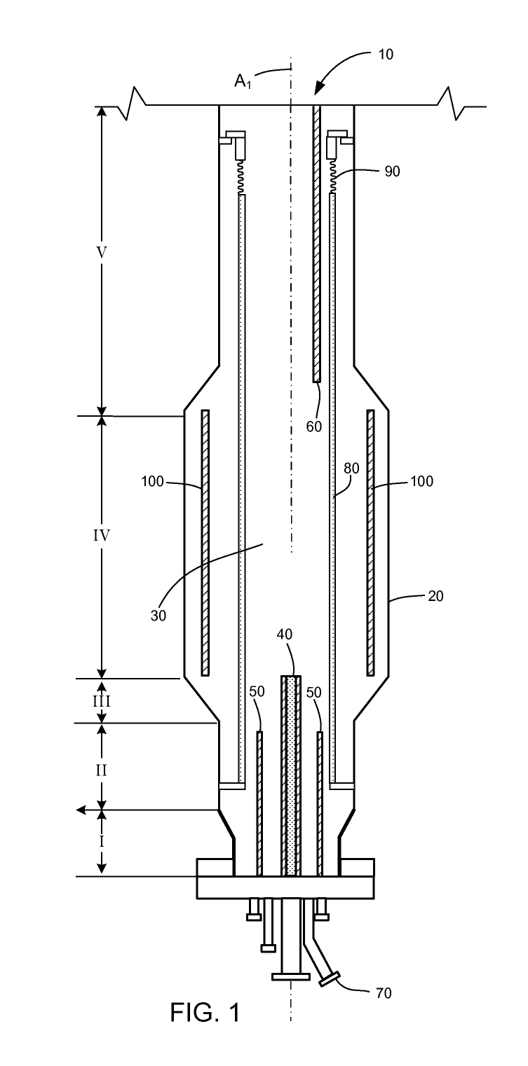

FIG. 1 is a simplified schematic overview of a fluidized bed reactor 10 for producing silicon-coated particles. The reactor 10 extends generally vertically, has an outer wall 20, a central axis A₁, and may have cross-sectional dimensions that are different at different elevations. The reactor shown in FIG. 1 has five regions I-V of differing cross-sectional dimensions at various elevations. The reaction chamber may be defined by walls of different cross-sectional dimensions, which may cause the upward flow of gas through the reactor to be at different velocities at different elevations. Silicon-coated particles are grown by pyrolytic decomposition of a silicon-bearing gas within a reactor chamber 30 and deposition of silicon onto particles within a fluidized bed. One or more inlets 40 are provided to admit a primary gas, e.g., a silicon-bearing gas or a mixture of silicon-bearing gas, hydrogen and/or an inert gas (e.g., helium, argon) into the reactor chamber. The reactor further includes one or more fluidization gas inlets 50. Additional hydrogen and/or inert gas can be delivered into the reactor through fluidization inlet(s) 50 to provide sufficient gas flow to fluidize the particles within the reactor bed. At the outset of production and during normal operations, seed particles are introduced into reactor 10 through a seed inlet 60. Silicon-coated particles are harvested by removal from reactor 10 through one or more product outlets 70.

A liner 80 extends vertically through the reactor 10. In some arrangements, the liner is concentric with the reactor. The illustrated liner is generally cylindrical, having a generally circular cross-section. However, portions of the liner may have varying diameters. For example, if region V of reactor 10 has a larger diameter of region IV, then the portion of liner in region V may similarly have a larger diameter than portions of the liner extending through regions II-IV. In some arrangements, an expansion joint system includes a liner expansion device 90 that extends upwardly from the upper surface of the liner 80. Liner expansion device 90 can compress to allow for thermal expansion of the liner 80 during operation of reactor 10. The liner can be of different material than the reactor vessel, but advantageously is constructed from material that will not contaminate the silicon product particles and is suitable for tolerating the temperature gradients associated with heating the fluid bed and cooling the product. Because the pressures internal and external to the liner are similar, the liner can be thin. In some systems, the liner has a thickness of 2-20 mm, such as 5-15 mm, or 8-12 mm.

The reactor 10 further includes one or more heaters. In some embodiments, the reactor includes a circular array of heaters 100 located concentrically around reactor chamber 30 between liner 80 and outer wall 20. In some systems, a plurality of radiant heaters 100 is utilized with the heaters 100 spaced equidistant from one another.

The temperature in the reactor differs in various portions of the reactor. For example, when operating with silane as the silicon-containing compound from which silicon is to be released in the manufacture of polysilicon, the temperature in region I, i.e., the bottom zone, is ambient temperature to 100° C. (FIG. 1). In region II, i.e., the cooling zone, the temperature typically ranges from 50-700° C. In region III, the intermediate zone, the temperature is substantially the same as in region IV. The central portion of region IV, i.e., the reaction and splash zone, is maintained at 620-760° C., and advantageously at 660-690° C., with the temperature increasing to 700-900° C. near the walls of region IV, i.e., the radiant zone. The upper portion of region V, i.e., the quench zone, has a temperature of 400-450° C.

To distribute and mitigate mechanical and thermal stresses, ceramic, graphite, and quartz liners may include upper and/or lower metal segments. However, metal segments can be a source of product contamination. Soft metals, for example, are prone to galling (wear and transfer of material between metallic surfaces in direct contact with relative movement) from contact with fluidized silicon particles. Silicon particles can be contaminated by the transferred metal. Galling also causes wear and tear of the metal segments, leading to reactor downtime as the liner is replaced or the metal surfaces are ground or machined to return them to condition for reuse. Thus, there is a need for an improved metallic segment that will better withstand reactor conditions, reduce product contamination, or both.

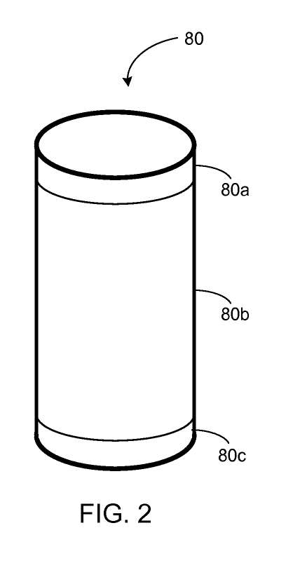

Disclosed embodiments of liner 80 include an upper portion 80a, a mid portion 80b, and a lower portion 80c (FIG. 2). The relative heights of portions 80a, 80b, and 80c may differ from the illustrated embodiment of FIG. 2. For example, upper portion 80a may have a different height than lower portion 80c. Mid portion 80b may be a unitary piece, or it may be constructed of a plurality of sections. In some embodiments, lower portion 80c extends through region I of the reactor 10 (FIG. 1). In certain embodiments, lower portion 80c also extends through region II of the reactor. Advantageously, mid portion 80b extends through regions III and IV of the reactor. Upper portion 80a may be positioned in region V of the reactor.

At least a portion of inner surface of lower portion 80c is a stainless steel alloy. In some embodiments, lower portion 80c consists essentially of a stainless steel alloy. Mid portion 80b comprises a material other than a stainless steel alloy. In some embodiments, at least a portion of an inner surface of the mid portion is ceramic, graphite, or glass. In certain embodiments, at least a portion of the inner surface of the mid portion is silicon carbide, silicon nitride, graphite, or quartz. In one embodiment, the mid portion consists essentially of the ceramic, graphite, or glass. In some arrangements, mid portion 80b is constructed of silicon carbide, silicon nitride, graphite, or quartz, and lower portion 80c is constructed of a stainless steel alloy. In some embodiments, upper portion 80a is constructed of a ceramic, graphite, glass, stainless steel, or a combination thereof. In one embodiment, upper portion 80a and mid portion 80b are constructed of the same material. In another embodiment, upper portion 80a and mid portion 80b are constructed of the different materials. In certain embodiments, upper portion 80a is constructed of a stainless steel alloy. Upper portion 80a and lower portion 80c may be constructed of the same or different stainless steel alloys.

Stainless steel alloys comprise iron and chromium. Stainless steel alloys typically also include at least trace amounts of one or more other elements including, but not limited to, carbon, nickel, manganese, molybdenum, silicon, phosphorus, nitrogen, sulfur, aluminum, arsenic, antimony, bismuth, cobalt, copper, niobium, selenium, tantalum, titanium, tungsten, vanadium, or combinations thereof. Stainless steel alloys are categorized as austenitic, ferritic, martensitic, or duplex (mixed microstructure of austenite and ferrite) based on their crystal structure.

Austenitic stainless steels have a face-centered cubic crystal structure, a minimum of 16% (w/w) chromium, and contain sufficient nickel and/or manganese to stabilize the austenite structure. A common austenitic stainless steel is type 304 with 18% (w/w) chromium and 8% (w/w) nickel. Austenitic stainless steels are not hardenable by heat treatment, and are not magnetic.

Ferritic stainless steels have a body-centered cubic crystal structure, typically 10.5-27% (w/w) chromium, and little or no nickel; several ferritic stainless steels also include molybdenum. Ferritic stainless steels have reduced corrosion resistance compared to austenitic stainless steels, and are ferromagnetic. Ferritic stainless steels are not hardenable by heat treatment.

Martensitic stainless steels have a body-centered tetragonal crystal structure, less than 20% (w/w) chromium, and less than 6% (w/w) nickel. They may include up to 1.2% (w/w) carbon. Martensitic stainless steels may include trace amounts (e.g., ≦1% (w/w)) of other elements including, but not limited to, silicon, manganese, phosphorus, sulfur, molybdenum, niobium, tungsten, vanadium, nitrogen, copper, selenium, or combinations thereof. Martensitic stainless steels are less corrosion resistant that austenitic and ferritic stainless steels, but are extremely strong, highly machinable, and can be hardened by heat treatment. Martensitic stainless steels are ferromagnetic.

Embodiments of the disclosed liner 80 include a lower portion 80c comprising a martensitic stainless steel alloy. The stainless steel alloy of lower portion 80c comprises less than 20% (w/w) chromium, such as 11-18% (w/w) chromium, and less than 6% (w/w) nickel. In some embodiments, the stainless steel alloy comprises less than 3% (w/w) nickel, such as less than 1% (w/w) nickel, less than 0.8% (w/w) nickel, less than 0.5% (w/w) nickel, or substantially no nickel. In certain embodiments, the stainless steel alloy does not comprise copper and/or selenium.

In one embodiment, the stainless steel alloy comprises 11.5-13.5% (w/w) chromium and 0.7-0.8% (w/w) nickel. In another embodiment, the alloy comprises 12-14% (w/w) chromium and less than 0.5% (w/w) nickel. In either of these embodiments, the alloy may further comprise ≦0.15% (w/w) carbon, ≦1% (w/w) silicon, ≦1% (w/w) manganese, ≦0.04% (w/w) phosphorus, and ≦0.03% (w/w) sulfur.

In yet another embodiment, the stainless steel alloy comprises 16-18% (w/w) chromium. The alloy may further comprise 0.5-1.5% (w/w) carbon, ≦1% (w/w) silicon, ≦1% (w/w) manganese, ≦0.04% (w/w), phosphorus, and ≦0.03% (w/w) sulfur.

In some embodiments, the upper portion 80a of the liner 80 comprises a stainless steel alloy, which may have the same, substantially similar, or a different composition than the stainless steel alloy of lower portion 80c. The term “substantially similar” composition means that the chromium content of the stainless steel alloys differs by no more than 2% (w/w).

Chemical composition and heat treatment contribute to hardness of martensitic stainless steels. Increased hardness reduces product contamination by, for example, reducing galling, which transfers material from the liner to fluidized silicon particles that contact the liner. Rockwell hardness is a hardness scale based on indentation hardness, i.e., the depth of penetration of an indenter under a particular load. Rockwell hardness can be measured on one of several scales with either a diamond cone or a steel sphere. Rockwell hardness scale C (“Rc”), for example, utilizes a 150 kgf load and a 120° diamond cone indenter. A larger number for the hardness indicates a harder material. In some embodiments, the liner's lower portion is constructed from a martensitic stainless steel alloy having a Rockwell hardness greater than 40 Rc, such as a Rockwell hardness from 45-60 Rc.

In some embodiments, lower portion 80c of the liner is prepared by machining a body of a stainless steel alloy, and then hardening the machined liner portion by heat treatment. For example, the alloy may be heated to a temperature from 900-1100° C. for an effective period of time, and then quenched (i.e., quickly cooled) in air, water, or oil. Optionally, the alloy is tempered after hardening to reduce its brittleness.

In some embodiments, the lower portion 80c of the liner comprises a stainless steel alloy having a mean coefficient of thermal expansion less than 15×10⁻⁶ m/m·° C. over a temperature range from 0° C.-315° C., such as from 9.9×10⁻⁶ m/m·° C. to 11.5×10⁻⁶ m/m·° C. In one embodiment, the stainless steel alloy has a mean coefficient of thermal expansion from 10.0×10⁻⁶ m/m·° C. to 10.2×10⁻⁶ m/m·° C. In another embodiment, the stainless steel alloy has a mean coefficient of thermal expansion from 10.7×10⁻⁶ m/m·° C. to 10.9×10⁻⁶ m/m·° C. In yet another embodiment, the stainless steel alloy has a mean coefficient of thermal expansion from 11.3×10⁻⁶ m/m·° C. to 11.5×10⁻⁶ m/m·° C.

In view of the many possible embodiments to which the principles of the disclosed invention may be applied, it should be recognized that the illustrated embodiments are only preferred examples of the invention and should not be taken as limiting the scope of the invention. Rather, the scope of the invention is defined by the following claims. We therefore claim as our invention all that comes within the scope and spirit of these claims.

We claim:

1. A reaction chamber liner for use in a heated silicon deposition reactor, the liner having an inner surface configured to define a portion of a reaction chamber, the inner surface comprising:
an upper portion;
a mid portion comprising a material other than a stainless steel alloy; and
a lower portion wherein at least a portion of the inner surface of the lower portion is a martensitic stainless steel alloy.

2. The liner of claim 1, wherein the stainless steel alloy comprises less than 20% (w/w) chromium and less than 3% (w/w) nickel.

3. The liner of claim 1, wherein the stainless steel alloy does not comprise copper or selenium.

4. The liner of claim 1, wherein the stainless steel alloy comprises 11-18% (w/w) chromium.

5. The liner of claim 4, wherein the stainless steel alloy comprises 11.5-13.5% (w/w) chromium and 0.7-0.8% (w/w) nickel.

6. The liner of claim 5, wherein the stainless steel alloy further comprises ≦0.15% (w/w) carbon, ≦1% (w/w) silicon, ≦1% (w/w) manganese, ≦0.04% (w/w) phosphorus, and ≦0.03% (w/w) sulfur.

7. The liner of claim 4, wherein the stainless steel alloy comprises 12-14% (w/w) chromium and less than 0.5% (w/w) nickel.

8. The liner of claim 7, wherein the stainless steel alloy further comprises ≦0.15% (w/w) carbon, ≦1% (w/w) silicon, ≦1% (w/w) manganese, ≦0.04% (w/w) phosphorus, and ≦0.03% (w/w) sulfur.

9. The liner of claim 4, wherein the stainless steel alloy comprises 16-18% (w/w) chromium and less than 0.5% (w/w) nickel.

10. The liner of claim 9, wherein the stainless steel alloy further comprises 0.5-1.5% (w/w) carbon, ≦1% (w/w) silicon, ≦1% (w/w) manganese, ≦0.04% (w/w), phosphorus, and ≦0.03% (w/w) sulfur.

11. The liner of claim 1, wherein the stainless steel alloy has a Rockwell hardness greater than 40 Rc.

12. The liner of claim 1, wherein the stainless steel alloy has a mean coefficient of thermal expansion less than 15×10⁻⁶ m/m·° C. over a temperature range from 0° C.-315° C.

13. The liner of claim 12, wherein the mean coefficient of thermal expansion is from 9.9×10⁻⁶ m/m·° C. to 11.5×10⁻⁶ m/m·° C.

14. The liner of claim 1, wherein the lower portion of the liner is prepared by machining a body of the stainless steel alloy and subsequently hardening and optionally tempering the stainless steel alloy by heat treatment.

15. The liner of claim 1, wherein the upper portion of the liner has a composition substantially similar to the lower portion.

16. The liner of claim 1, wherein at least a portion of the inner surface of the mid portion is a ceramic, graphite, or glass.

17. The liner of claim 16, wherein the mid portion consists essentially of the ceramic, graphite, or glass.

18. The liner of claim 16, wherein the ceramic is silicon carbide or silicon nitride.

19. The liner of claim 16, wherein the glass is quartz.

20. A heated silicon deposition reactor system, comprising:
a vessel having an outer wall;
at least one heater position inwardly of the outer wall;
a liner according to claim 1, wherein the liner is positioned inwardly of the at least one heater such that the inner surface of the liner defines a portion of a reaction chamber;
at least one inlet having an opening positioned to admit a primary gas comprising a silicon-bearing gas into the reaction chamber;
a plurality of fluidization inlets, wherein each fluidization inlet has an outlet opening into the reaction chamber; and
at least one outlet for removing silicon-coated product particles from the vessel.
